(19) United States
(12) Patent Application Publication
(10) Pub. No.: US 2026/0143629 A1
(43) Pub. Date: May 21, 2026

(54) INFORMATION HANDLING SYSTEM INCLUDING AN ABSORBENT MATERIAL

(71) Applicant: Dell Products L.P., Round Rock, TX (US)

(72) Inventors: EDUARDO ESCAMILLA, Round Rock, TX (US); ERIC MICHAEL TUNKS, Austin, TX (US)

(21) Appl. No.: 18/948,930

(22) Filed: Nov. 15, 2024

(51) Int. Cl. H05K 7/20; G06F 1/20

(52) U.S. Cl. CPC H05K 7/20272; G06F 1/206; H05K 7/20154

(57) ABSTRACT

An information handling system, including a chassis, including: a computing component; a cooling system to provide temperature management of at least the computing component, the cooling system including: a plurality of fluid lines for transporting liquid proximate to the computing component, the liquid configured to provide cooling of the computing component; a coupling connector between a first fluid line and a second fluid line of the plurality of fluid lines; and an absorbent material positioned on a surface of the chassis proximate to the coupling connector such that the absorbent material is configured to absorb fluid that leaks from the coupling connector.

### BACKGROUND

### Field of the Disclosure

The disclosure relates generally to an information handling system, and in particular, an information handling system including an absorbent material.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems rely on cooling systems, such as fans, heat sinks, and liquid coolers, to dissipate the heat generated by their components, ensuring optimal performance and longevity. Liquid cooling systems, in particular, use a liquid coolant to transfer heat away from the CPU, GPU, and other critical parts. However, these liquid systems can sometimes leak, which may occur due to faulty seals, cracked tubes, or improper installation. Coolant leaks can cause significant damage to the hardware of the information handling system, leading to malfunctions, electrical shorts, and potentially complete system failure if not promptly addressed.

### SUMMARY

Innovative aspects of the subject matter described in this specification may be embodied in an information handling system, including a chassis, including: a computing component; a cooling system to provide temperature management of at least the computing component, the cooling system including: a plurality of fluid lines for transporting liquid proximate to the computing component, the liquid configured to provide cooling of the computing component; a coupling connector between a first fluid line and a second fluid line of the plurality of fluid lines; and an absorbent material positioned on a surface of the chassis proximate to the coupling connector such that the absorbent material is configured to absorb fluid that leaks from the coupling connector.

Other embodiments of these aspects include corresponding systems and apparatus.

These and other embodiments may each optionally include one or more of the following features. For instance, an air flow system to provide airflow across the computing component and proximate to the fluid lines, wherein the absorbent material does not obstruct the airflow. The absorbent material has a first thickness when in a first state, the absorbent material has a second thickness when in a second state, the second thickness greater than the first thickness, and the absorbent material not obstructing the airflow when in the first state. The first thickness of the absorbent material when in the first state does not obstruct the airflow. The absorbent material transitions from the first state to the second state in response to the absorbent material absorbing fluid that leaks from the coupling connector. The chassis further includes a reservoir at the surface, the absorbent material positioned at least in the reservoir. The absorbent material is a sponge-based material. The absorbent material includes a super absorbent polymer (SAP). One or more sensors positioned on the bottom surface proximate to the coupling connector, the sensors configured to detect liquid at the surface of the chassis and/or the absorbent material, and generate a signal in response to the detection of liquid. The computing component is a printed circuit board (PCB).

Particular implementations of the subject matter described in this specification can be implemented so as to realize one or more of the following advantages. For example, a hold up time of an information handling system (server) is increased.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a block diagram of the information handling system including the absorbent material.

FIG. 3 illustrates a simplified side view of the information handling system showing the cooling system and the air flow system, with the absorbent material in a first state, in a first example.

FIG. 4 illustrates a simplified side view of the information handling system showing the cooling system and the air flow system, with the absorbent material in a second state, in the first example.

FIG. 5 illustrates a simplified side view of the information handling system showing the cooling system and the air flow system, with the absorbent material in a first state, in a second example.

FIG. 6 illustrates a simplified side view of the information handling system showing the cooling system and the air flow system, with the absorbent material in a second state, in the second example.

FIG. 7 illustrates a chassis of the information handling system, in a first example.

FIG. 8 illustrates a chassis of the information handling system, in a second example.

FIG. 9 illustrates a chassis of the information handling system, in a third example.

FIG. 10 illustrates a simplified side view of the information handling system showing the cooling system and the air flow system, with the absorbent material in a first state, in a third example.

FIG. 11 illustrates a simplified side view of the information handling system showing the cooling system and the air flow system, with the absorbent material in a second state, in the third example.

FIG. 12 illustrates a simplified side view of the information handling system showing the cooling system and the air flow system, with the absorbent material in a first state, in a fourth example.

FIG. 13 illustrates a simplified side view of the information handling system showing the cooling system and the air flow system, with the absorbent material in a second state, in the fourth example.

### DESCRIPTION OF PARTICULAR EMBODIMENT(S)

This disclosure discusses an information handling system including an absorbent material. In short, the absorbent material can absorb fluid that leaks from fluid lines and/or coupling connectors, described further herein.

Specifically, this disclosure discusses an information handling system, including: a chassis, including: a computing component; a cooling system to provide temperature management of at least the computing component, the cooling system including: a plurality of fluid lines for transporting liquid proximate to the computing component, the liquid configured to providing cooling of the component; a coupling connector between a first fluid line and a second fluid line of the plurality of fluid lines; and an absorbent material positioned on a surface of the chassis proximate to the coupling connector such that the absorbent material is configured to absorb fluid that leaks from the coupling connector.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

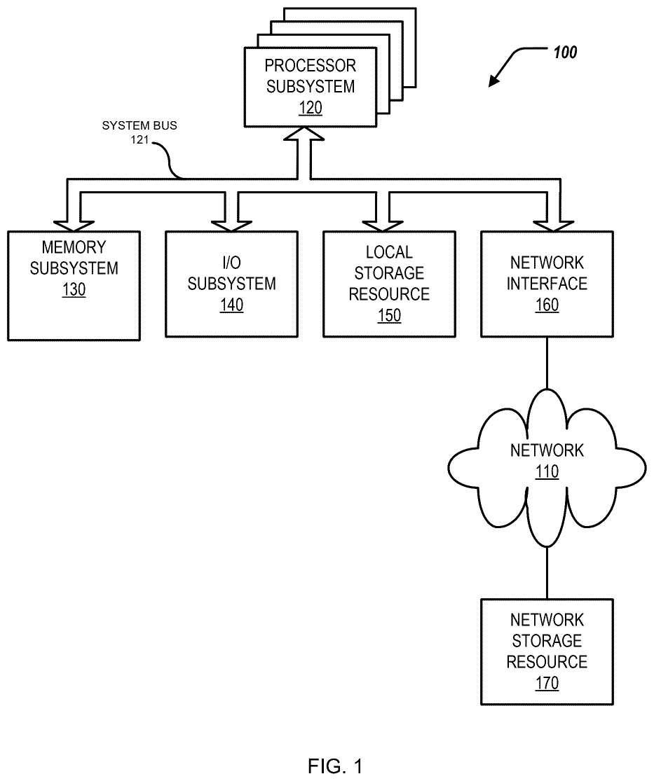

Particular embodiments are best understood by reference to FIGS. 1-9 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of the information handling system). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

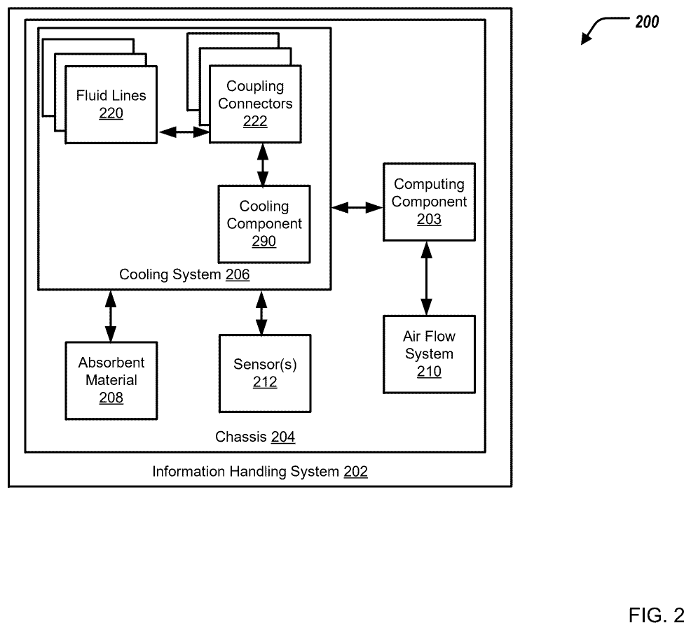

Turning to FIG. 2, FIG. 2 illustrates an environment 200 including an information handling system 202. The information handling system 202 can include a chassis 204. The chassis 204 can include a computing component 203, a cooling system 206, an absorbent material 208, an air flow system 210, and sensor(s) 212. The cooling system 206 can include one or more fluid lines 220, coupling connectors 222, and a cooling component 290. In some examples, the cooling component 290 includes a pump or a heat sink. In some examples, the information handling system 202 is similar to, or includes, the information handling system 100 of FIG. 1.

In short, the absorbent material 208 can absorb fluid that leaks from the fluid lines 220 and/or from the coupling connectors 222, described further herein.

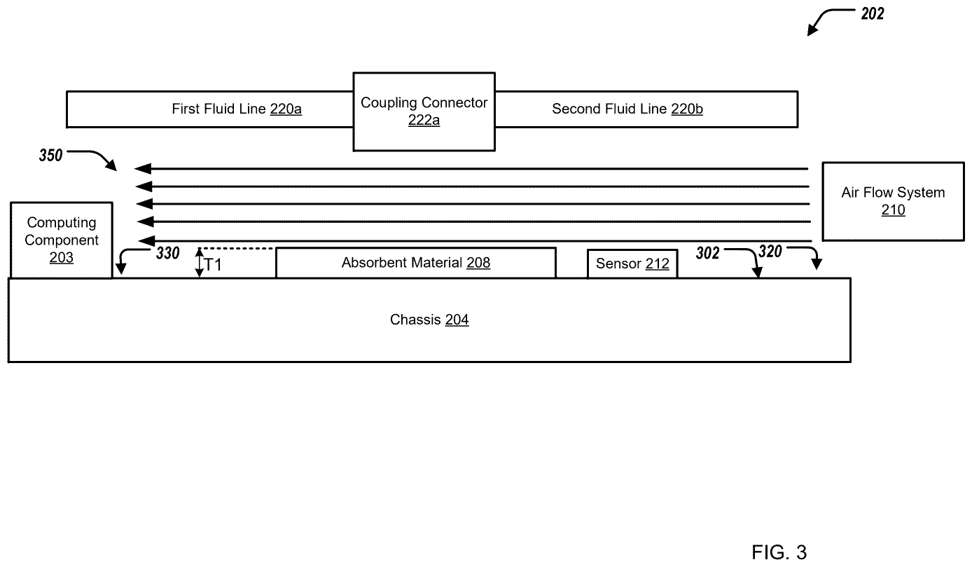

FIG. 3 illustrates a simplified side view of at least a portion of the information handling system 202 showing components of the cooling system 206 and the air flow system 210, with the absorbent material 208 in a first state, in a first example. The chassis 204 includes a surface 302. In some examples, the computing component 203 can be positioned on the surface 302. In some examples, the computing component 203 is positioned anywhere with respect to the chassis 204. In some examples, the computing component 203 is a printed circuit board (PCB).

The cooling system 206 (shown in FIG. 2) can provide temperature management of the computing component 203. Specifically, the cooling system 206 can include a first fluid line 220a and a second fluid line 220b. The first fluid line 220a and the second fluid line 220b can transport liquid (liquid/fluid/coolant) proximate to the computing component 203, via a pump (not shown) or similar apparatus. In other words, the pump (not shown) can pump fluid in the first fluid line 220a and the second fluid line 220b proximate to the computing component 203 to provide temperature management of the computing component 203, and in particular, the liquid/fluid of the first fluid line 220a and the second fluid line 220b is configured to provide cooling of the computing component 203. Furthermore, the cooling system 206 can include the coupling connector 222a. The coupling connector 222a can provide a physical coupling between the first fluid line 220a and the second fluid line 220b. That is, the coupling connector 222a can provide a physical coupling between the ends of the first fluid line 220a and the second fluid line 220b such that the fluid within the first fluid line 220a can be transported to the second fluid line 220b and fluid within the second fluid line 220b can be transported to the first fluid line 220a. The coupling connector 222a can form a seal around the first fluid line 220a and the second fluid line 220b. The coupling connector 222a can be formed from any material that forms the seal around the first fluid line 220a and the second fluid line 220b, such as plastic, metal, or the like. In some examples, the coupling connector 222a is formed from the same material as the first fluid line 220a and the second fluid line 220b. In some examples, the coupling connector 220a is formed from a different material as the first fluid line 220a and the second fluid line 220b. In some examples, the coupling connector 222a is coupled to the first fluid line 220a and the second fluid line 220b with adhesive.

The air flow system 210 can provide airflow 350 across the computing component 203 and proximate to the fluid lines 220a, 220b. The airflow system 210 can be coupled to the chassis 204, or any part of the information handling system 202. The airflow system 210 can include a fan or other apparatus for moving air from a first end 320 of the chassis 204 to a second end 330 of the chassis 204 opposite to the first end 320. In some examples, the air flow system 210 and the cooling system 206 can simultaneously provide temperature management of the computing component 203. In some examples, the air flow system 210 and the cooling system 206 can provide temperature management of the computing component 203 independently.

The information handling system 202 can further include the sensor 212 (or sensors 212). The sensor 212 can be positioned on the surface 302 of the chassis 204; however, the sensor 212 can be positioned anywhere within the information handling system 202. The sensor 212 can be positioned proximate to the absorbent material 208 and/or the coupling connector 222a. The sensor 212 can detect liquid. In some examples, the sensor 212 is an optical light sensor, and/or an optical light rope sensor.

The information handling system 202 can further include the absorbent material 208. In some examples, the absorbent material 208 can be positioned on the surface 302 of the chassis 204. The absorbent material 208 is positioned proximate to the coupling connector 222a. In some examples, the absorbent material 208 is positioned in superimposition with the coupling connector 222a. The absorbent material 208 can be of a substantially rectangular cuboid shape, or any geometric shape as appropriate for absorption of fluid. In some examples, the absorbent material 208 is a sponge-based material. In some examples, the absorbent material 208 is a sponge. In some examples, the absorbent material 208 is a super absorbent polymer (SAP). In some examples, the absorbent material 208 is a combination of two or more of a sponge-based material, a sponge, and a SAP.

FIG. 3 illustrates a simplified side view of the information handling system 202 showing components of the cooling system 206 and the air flow system 210, in a first example, with the absorbent material 208 in a first state. The first fluid line 220a is coupled to the second fluid line 220b via the coupling connector 222a, in the first example. The absorbent material 208, in the first state, has a first thickness T1. When the absorbent material 208 is in the first state, the absorbent material 208 does not obstruct (or block) the airflow 350 from the air flow system 210. That is, the absorbent material 208 does not obstruct (or block) the airflow 350 from the air flow system 210 that is for moving air from the first end 320 of the chassis 204 to the second end 330 of the chassis 204 to provide temperature management of the computing component 203. Specifically, the first thickness T1 of the absorbent material 208 when in the first state does not obstruct (or block) the airflow 350 from the air flow system 210. That is, the first thickness T1 of the absorbent material 208 when in the first state is of a magnitude such that the absorbent material 208 does not partially or fully obstruct, impede, or block the airflow 350 from the air flow system 210. In some examples, the first thickness T1 of the absorbent material 208 when in the first state is “below” the airflow 350 from the air flow system 210. That is, the first thickness T1 of the absorbent material 208 when in the first state is “below” the airflow 350 from the air flow system 210 such that the airflow 350 from the air flow system 210 is “above” the absorbent material 208.

To that end, in some examples, fluid may egress from the first fluid line 220a and/or the second fluid line 220b. For example, fluid may egress from the first fluid line 220a and/or the second fluid line 220b at the coupling connector 222a. That is, fluid may leak from the first fluid line 220a and/or the second fluid line 220b at the coupling connector 222a—fluid may leak from the coupling connector 222a. For example, fluid may egress from the first fluid line 220a and/or the second fluid line 220b at a hole (puncture) of the first fluid line 220a and/or the second fluid 220b. The absorbent material 208 can absorb the fluid that leaks from the coupling connector 222a, the first fluid line 220a, and/or the second fluid line 220b. That is, as the absorbent material 208 is positioned proximate to the coupling connector 222a, the absorbent material 208 can absorb fluid that leaks from/at the coupling connector 222a. The absorbent material 208 can absorb such leaking fluid to minimize, if not prevent, liquid damage to the computing component 203, the chassis 204, and any other part of the information handling system 202.

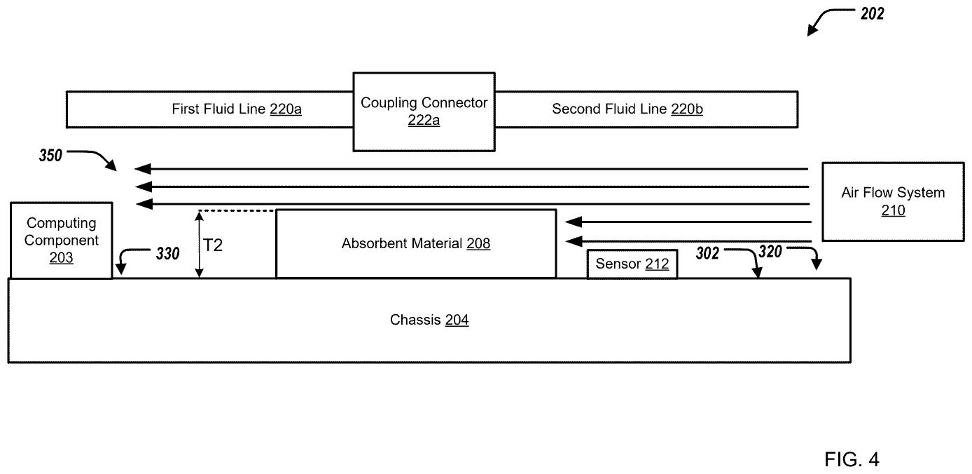

FIG. 4 illustrates a simplified side view of the information handling system 202 showing components of the cooling system 206 and the air flow system 210, in the first example, with the absorbent material 208 in a second state. Specifically, the absorbent material 208, in the second state, has a second thickness T2, with the second thickness T2 greater than the first thickness T1. To that end, when the absorbent material 208 absorbs liquid (e.g., liquid leaking from the fluid lines 220a, 220b at the coupling connector 222a), the absorbent material 208 transitions from the first state to the second state. That is, the absorbent material 208 transitions from the first state to the second state in response to the absorbent material 208 absorbing fluid that leaks from the coupling connector 222a.

In some cases, when the absorbent material 208 is in the second state, the absorbent material 208 partially obstructs (or blocks) the airflow 350 from the air flow system 210. That is, the absorbent material 208 partially obstructs (or blocks) the airflow 350 from the air flow system 210 that is for moving air from the first end 320 of the chassis 204 to the second end 330 of the chassis 204. Specifically, the second thickness T2 of the absorbent material 208 when in the second state partially obstructs (or blocks) the airflow 350 from the air flow system 210. That is, the second thickness T2 of the absorbent material 208 when in the second state is of a magnitude such that the absorbent material 208 partially obstructs, impedes, or blocks the airflow 350 from the air flow system 210. In some examples, the second thickness T2 of the absorbent material 208 when in the second state is “on-level” (or at the same “level”) with a portion of the airflow 350 from the air flow system 210. That is, the second thickness T2 of the absorbent material 208 when in the second state is “on-level” (or at the same “level”) with a portion of the airflow 350 from the air flow system 210 such that a portion of the airflow 350 from the air flow system 210 encounters the absorbent material 208.

In some examples, the sensor 212 can detect liquid at the surface 302 of the chassis 204 and/or liquid at the absorbent material 208. That is, when the absorbent material 208 absorbs liquid (e.g., liquid leaking from the fluid lines 220a, 220b at the coupling connector 222a), the sensor 212 can detect that the absorbent material 208 has absorbed liquid. Furthermore, in some cases, the absorbent material 208 can absorb a maximum physically allowable amount of liquid (e.g., based on the absorption proprieties of the absorbent material 208), and further liquid that is leaked (e.g., liquid leaking from the fluid lines 220a, 220b at the coupling connector 222a) can encounter the surface 302 of the chassis 204 (e.g., the liquid can “overflow” or “spill” from the absorbent material 208 to the surface 302 of the chassis 204). The sensor 212 can further detect the liquid at the surface 302 of the chassis 204.

The sensors 212, in response to detection of the liquid (at the chassis 204 and/or the absorbent material 208), can generate a signal. For example, a notification can be provided on a display device coupled to the information handling system 202 indicating the detection of fluid. For example, a notification can be provided to a third-party computing device in communication with the information handling system 202 indicating the detection of fluid. In some examples, the signal can initiate a shutdown of the information handling system 202.

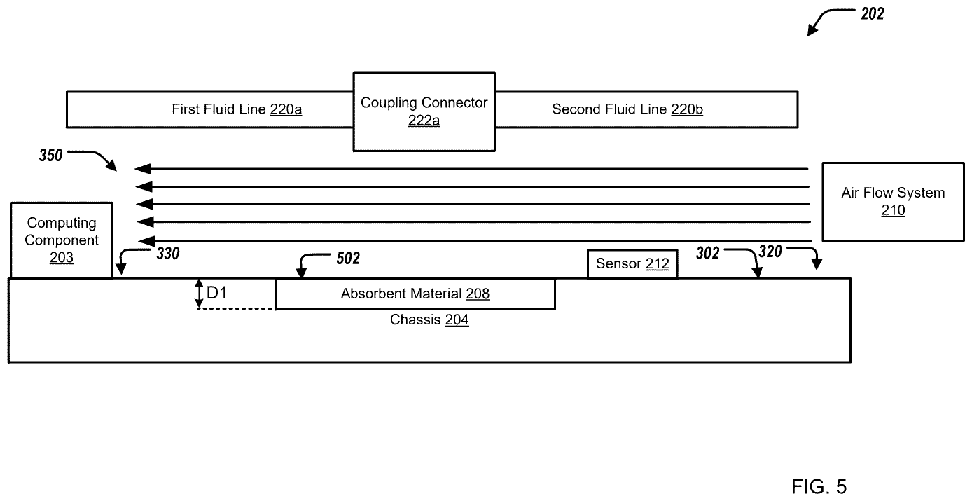

FIG. 5 illustrates a simplified side view of the information handling system 202 showing components of the cooling system 206 and the air flow system 210, in a second example, with the absorbent material 208 in a first state. The first fluid line 220a is coupled to the second fluid line 220b via the coupling connector 222a, in the second example. In the second example, the chassis 204 includes a reservoir (cavity, recession) 502 at the surface 302. In some examples, the absorbent material 208 is positioned in the reservoir 502. In some examples, the first thickness T1 of the absorbent material 208, when in the first state, is substantially the same, or the same, as a depth D1 of the reservoir 502. In some examples, the first thickness T1 of the absorbent material 208, when in the first state, is less than the depth D1 of the reservoir 502. In some examples, the first thickness T1 of the absorbent material 208, when in the first state, is greater than the depth D1 of the reservoir 502.

To that end, when the absorbent material 208 is in the first state and positioned within the reservoir 502, the absorbent material 208 does not obstruct (or block) the airflow 350 from the air flow system 210. That is, the absorbent material 208, when positioned within the reservoir 502, does not obstruct (or block) the airflow 350 from the air flow system 210 that is moving air from the first end 320 of the chassis 204 to the second end 330 of the chassis 204 to provide temperature management of the computing component 203. Specifically, the first thickness T1 of the absorbent material 208 when in the first state does not obstruct (or block) the airflow 350 from the air flow system 210 when positioned within the reservoir 502. That is, the first thickness T1 of the absorbent material 208 when in the first state is of a magnitude such that the absorbent material 208 does not partially or fully obstruct, impede, or block the airflow 350 from the air flow system 210 when positioned within the reservoir 502. In some examples, the first thickness T1 of the absorbent material 208 when in the first state is “below” the airflow 350 from the air flow system 210 when positioned within the reservoir 502. That is, the first thickness T1 of the absorbent material 208 when in the first state is “below” the airflow 350 from the air flow system 210 such that the airflow 350 from the air flow system 210 is “above” the absorbent material 208 when positioned within the reservoir 502.

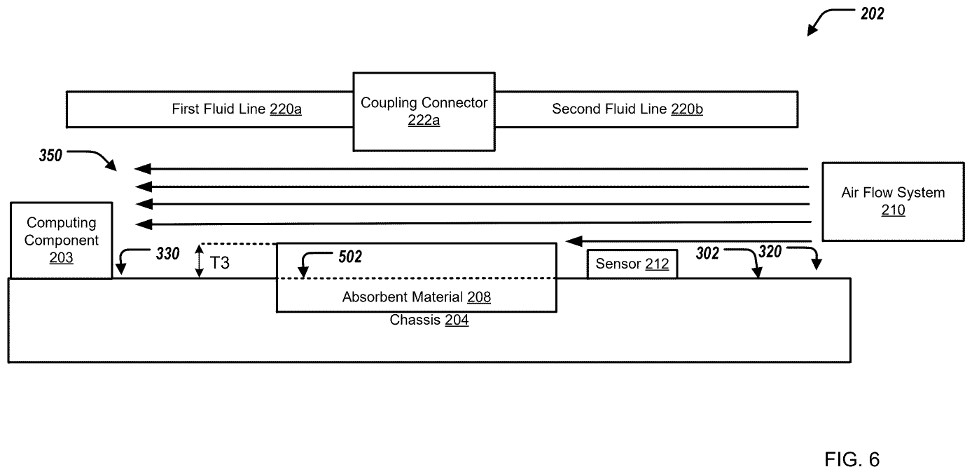

FIG. 6 illustrates a simplified side view of the information handling system 202 showing components of the cooling system 206 and the air flow system 210, in the second example, with the absorbent material 208 in the second state. Specifically, the absorbent material 208 from the surface 302, in the second state, has a second thickness T3, with the third thickness T3 less than the second thickness T2. To that end, when the absorbent material 208 absorbs liquid (e.g., liquid leaking from the fluid lines 220a, 220b at the coupling connector 222a), the absorbent material 208 transitions from the first state to the second state. That is, the absorbent material 208 transitions from the first state to the second state in response to the absorbent material 208 absorbing fluid that leaks from the coupling connector 222a.

In some cases, when the absorbent material 208 is in the second state, the absorbent material 208 partially obstructs (or blocks) the airflow 350 from the air flow system 210. That is, the absorbent material 208 partially obstructs (or blocks) the airflow 350 from the air flow system 210 that is for moving air from the first end 320 of the chassis 204 to the second end 330 of the chassis 204. Specifically, the third thickness T3 of the absorbent material 208 when in the second state partially obstructs (or blocks) the airflow 350 from the air flow system 210. That is, the third thickness T3 of the absorbent material 208 when in the second state is of a magnitude such that the absorbent material 208 partially obstructs, impedes, or blocks the airflow 350 from the air flow system 210. In some examples, the third thickness T3 of the absorbent material 208 when in the second state is “on-level” with a portion of the airflow 350 from the air flow system 210. That is, the third thickness T3 of the absorbent material 208 when in the second state is “on-level” with a portion of the airflow 350 from the air flow system 210 such that a portion of the airflow 350 from the air flow system 210 encounters the absorbent material 208.

In some examples, as the absorbent material 208 is positioned within the reservoir 502, and the third thickness T3 is less than the second thickness T2, the absorbent material 208, in the second example, partially obstructs, impedes, or blocks a portion of the airflow 350 from the air flow system 210 less than the amount of airflow 350 that is blocked by the absorbent material 208, in the first example, when both are in the second state.

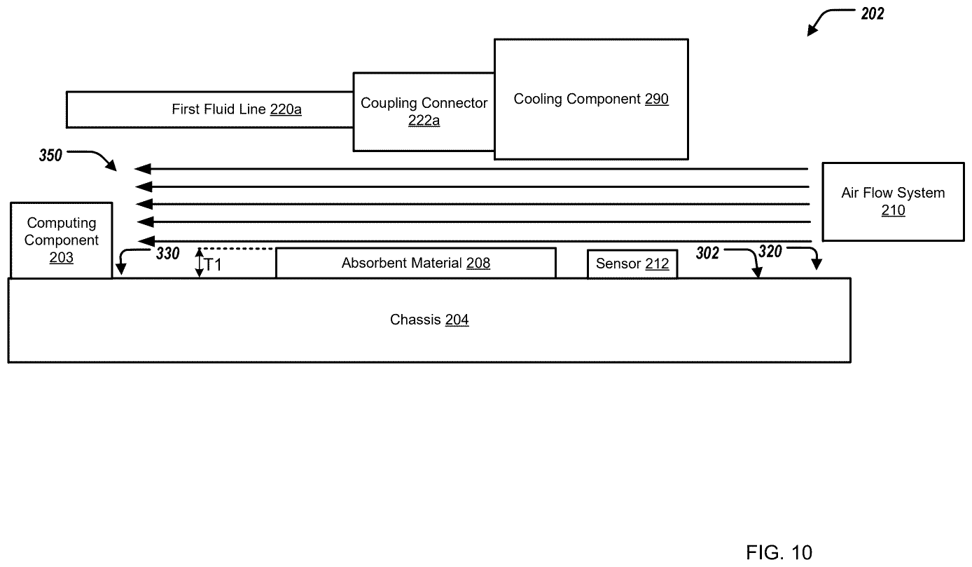

FIG. 10 illustrates a simplified side view of the information handling system 202 showing components of the cooling system 206 and the air flow system 210, in a third example, with the absorbent material 208 in a first state. The first fluid line 220a is coupled to the cooling component 290 via the coupling connector 222a, in the third example. The absorbent material 208, in the first state, has a first thickness T1. When the absorbent material 208 is in the first state, the absorbent material 208 does not obstruct (or block) the airflow 350 from the air flow system 210. That is, the absorbent material 208 does not obstruct (or block) the airflow 350 from the air flow system 210 that is for moving air from the first end 320 of the chassis 204 to the second end 330 of the chassis 204 to provide temperature management of the computing component 203. Specifically, the first thickness T1 of the absorbent material 208 when in the first state does not obstruct (or block) the airflow 350 from the air flow system 210. That is, the first thickness T1 of the absorbent material 208 when in the first state is of a magnitude such that the absorbent material 208 does not partially or fully obstruct, impede, or block the airflow 350 from the air flow system 210. In some examples, the first thickness T1 of the absorbent material 208 when in the first state is “below” the airflow 350 from the air flow system 210. That is, the first thickness T1 of the absorbent material 208 when in the first state is “below” the airflow 350 from the air flow system 210 such that the airflow 350 from the air flow system 210 is “above” the absorbent material 208.

To that end, in some examples, fluid may egress from the first fluid line 220a. For example, fluid may egress from the first fluid line 220a at the coupling connector 222a. That is, fluid may leak from the first fluid line 220a at the coupling connector 222a—fluid may leak from the coupling connector 222a. The absorbent material 208 can absorb the fluid that leaks from the coupling connector 222a, and/or the first fluid line 220a. That is, as the absorbent material 208 is positioned proximate to the coupling connector 222a, the absorbent material 208 can absorb fluid that leaks from/at the coupling connector 222a. The absorbent material 208 can absorb such leaking fluid to minimize, if not prevent, liquid damage to the computing component 203, the chassis 204, and any other part of the information handling system 202.

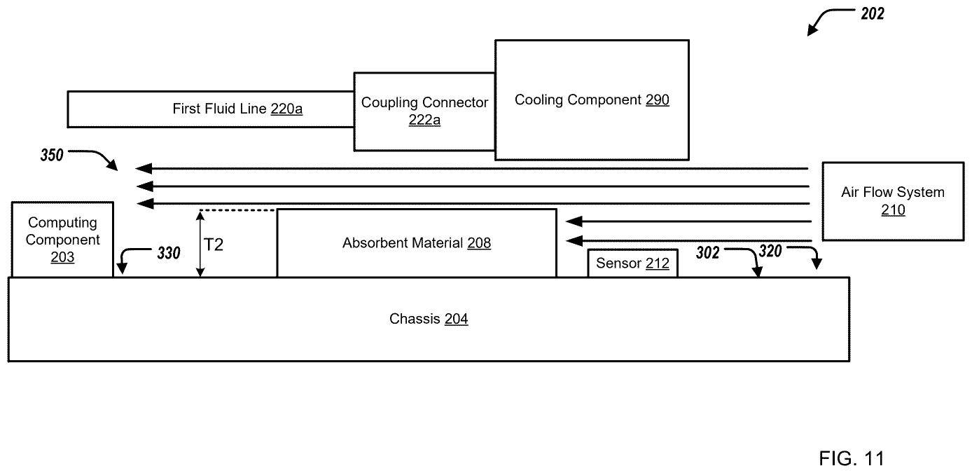

FIG. 11 illustrates a simplified side view of the information handling system 202 showing components of the cooling system 206 and the air flow system 210, in the third example, with the absorbent material 208 in a second state. Specifically, the absorbent material 208, in the second state, has a second thickness T2, with the second thickness T2 greater than the first thickness T1. To that end, when the absorbent material 208 absorbs liquid (e.g., liquid leaking from the fluid line 220a and/or the coupling connector 222a), the absorbent material 208 transitions from the first state to the second state. That is, the absorbent material 208 transitions from the first state to the second state in response to the absorbent material 208 absorbing fluid that leaks from the coupling connector 222a.

In some cases, when the absorbent material 208 is in the second state, the absorbent material 208 partially obstructs (or blocks) the airflow 350 from the air flow system 210. That is, the absorbent material 208 partially obstructs (or blocks) the airflow 350 from the air flow system 210 that is for moving air from the first end 320 of the chassis 204 to the second end 330 of the chassis 204. Specifically, the second thickness T2 of the absorbent material 208 when in the second state partially obstructs (or blocks) the airflow 350 from the air flow system 210. That is, the second thickness T2 of the absorbent material 208 when in the second state is of a magnitude such that the absorbent material 208 partially obstructs, impedes, or blocks the airflow 350 from the air flow system 210. In some examples, the second thickness T2 of the absorbent material 208 when in the second state is “on-level” (or at the same “level”) with a portion of the airflow 350 from the air flow system 210. That is, the second thickness T2 of the absorbent material 208 when in the second state is “on-level” (or at the same “level”) with a portion of the airflow 350 from the air flow system 210 such that a portion of the airflow 350 from the air flow system 210 encounters the absorbent material 208.

In some examples, the sensor 212 can detect liquid at the surface 302 of the chassis 204 and/or liquid at the absorbent material 208. That is, when the absorbent material 208 absorbs liquid (e.g., liquid leaking from the fluid line 220a and/or at the coupling connector 222a), the sensor 212 can detect that the absorbent material 208 has absorbed liquid. Furthermore, in some cases, the absorbent material 208 can absorb a maximum physically allowable amount of liquid (e.g., based on the absorption proprieties of the absorbent material 208), and further liquid that is leaked (e.g., liquid leaking from the fluid line 220a and/or at the coupling connector 222a) can encounter the surface 302 of the chassis 204 (e.g., the liquid can “overflow” or “spill” from the absorbent material 208 to the surface 302 of the chassis 204). The sensor 212 can further detect the liquid at the surface 302 of the chassis 204.

The sensors 212, in response to detection of the liquid (at the chassis 204 and/or the absorbent material 208), can generate a signal. For example, a notification can be provided on a display device coupled to the information handling system 202 indicating the detection of fluid. For example, a notification can be provided to a third-party computing device in communication with the information handling system 202 indicating the detection of fluid. In some examples, the signal can initiate a shutdown of the information handling system 202.

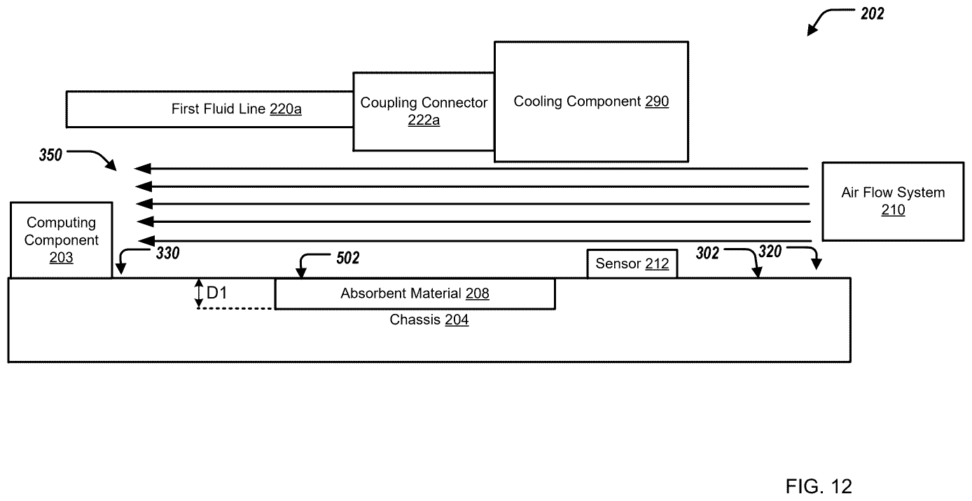

FIG. 12 illustrates a simplified side view of the information handling system 202 showing components of the cooling system 206 and the air flow system 210, in a fourth example, with the absorbent material 208 in a first state. The first fluid line 220a is coupled to the cooling component 290 via the coupling connector 222a, in the fourth example. In the fourth example, the chassis 204 includes a reservoir (cavity, recession) 502 at the surface 302. In some examples, the absorbent material 208 is positioned in the reservoir 502. In some examples, the first thickness T1 of the absorbent material 208, when in the first state, is substantially the same, or the same, as a depth D1 of the reservoir 502. In some examples, the first thickness T1 of the absorbent material 208, when in the first state, is less than the depth D1 of the reservoir 502. In some examples, the first thickness T1 of the absorbent material 208, when in the first state, is greater than the depth D1 of the reservoir 502.

To that end, when the absorbent material 208 is in the first state and positioned within the reservoir 502, the absorbent material 208 does not obstruct (or block) the airflow 350 from the air flow system 210. That is, the absorbent material 208, when positioned within the reservoir 502, does not obstruct (or block) the airflow 350 from the air flow system 210 that is moving air from the first end 320 of the chassis 204 to the second end 330 of the chassis 204 to provide temperature management of the computing component 203. Specifically, the first thickness T1 of the absorbent material 208 when in the first state does not obstruct (or block) the airflow 350 from the air flow system 210 when positioned within the reservoir 502. That is, the first thickness T1 of the absorbent material 208 when in the first state is of a magnitude such that the absorbent material 208 does not partially or fully obstruct, impede, or block the airflow 350 from the air flow system 210 when positioned within the reservoir 502. In some examples, the first thickness T1 of the absorbent material 208 when in the first state is “below” the airflow 350 from the air flow system 210 when positioned within the reservoir 502. That is, the first thickness T1 of the absorbent material 208 when in the first state is “below” the airflow 350 from the air flow system 210 such that the airflow 350 from the air flow system 210 is “above” the absorbent material 208 when positioned within the reservoir 502.

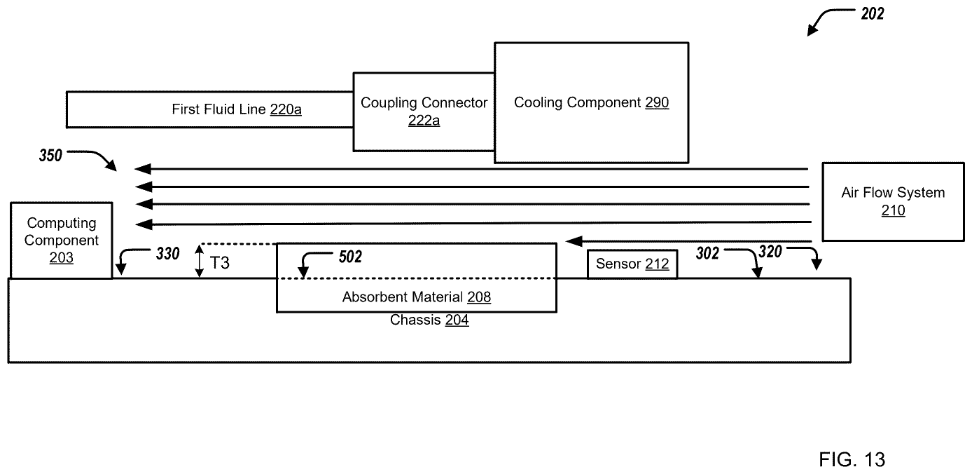

FIG. 13 illustrates a simplified side view of the information handling system 202 showing components of the cooling system 206 and the air flow system 210, in the fourth example, with the absorbent material 208 in the second state. Specifically, the absorbent material 208 from the surface 302, in the second state, has a second thickness T3, with the third thickness T3 less than the second thickness T2. To that end, when the absorbent material 208 absorbs liquid (e.g., liquid leaking from the fluid line 220a and/or the coupling connector 222a), the absorbent material 208 transitions from the first state to the second state. That is, the absorbent material 208 transitions from the first state to the second state in response to the absorbent material 208 absorbing fluid that leaks from the coupling connector 222a.

However, when the absorbent material 208 is in the second state, the absorbent material 208 partially obstructs (or blocks) the airflow 350 from the air flow system 210. That is, the absorbent material 208 partially obstructs (or blocks) the airflow 350 from the air flow system 210 that is for moving air from the first end 320 of the chassis 204 to the second end 330 of the chassis 204. Specifically, the third thickness T3 of the absorbent material 208 when in the second state partially obstructs (or blocks) the airflow 350 from the air flow system 210. That is, the third thickness T3 of the absorbent material 208 when in the second state is of a magnitude such that the absorbent material 208 partially obstructs, impedes, or blocks the airflow 350 from the air flow system 210. In some examples, the third thickness T3 of the absorbent material 208 when in the second state is “on-level” with a portion of the airflow 350 from the air flow system 210. That is, the third thickness T3 of the absorbent material 208 when in the second state is “on-level” with a portion of the airflow 350 from the air flow system 210 such that a portion of the airflow 350 from the air flow system 210 encounters the absorbent material 208.

In some examples, as the absorbent material 208 is positioned within the reservoir 502, and the third thickness T3 is less than the second thickness T2, the absorbent material 208, in the second example, partially obstructs, impedes, or blocks a portion of the airflow 350 from the air flow system 210 less than the amount of airflow 350 that is blocked by the absorbent material 208, in the first example, when both are in the second state.

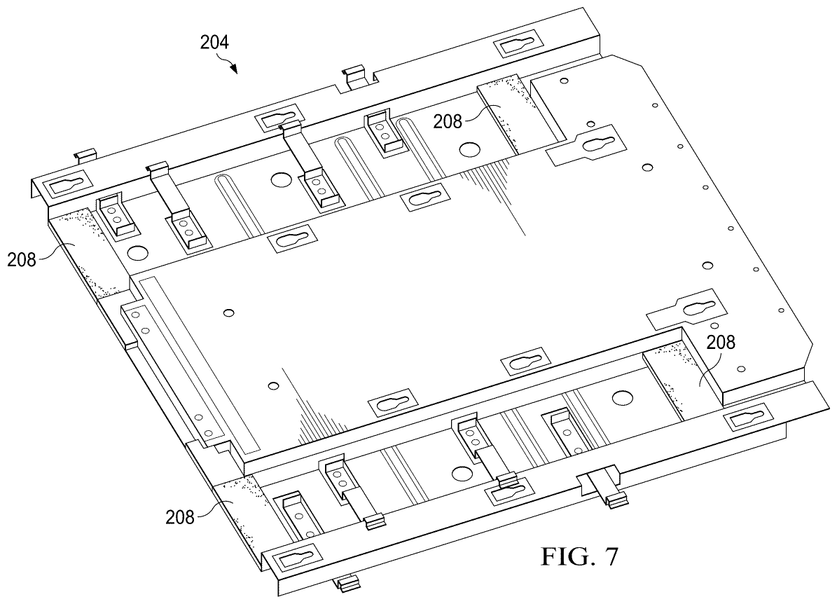

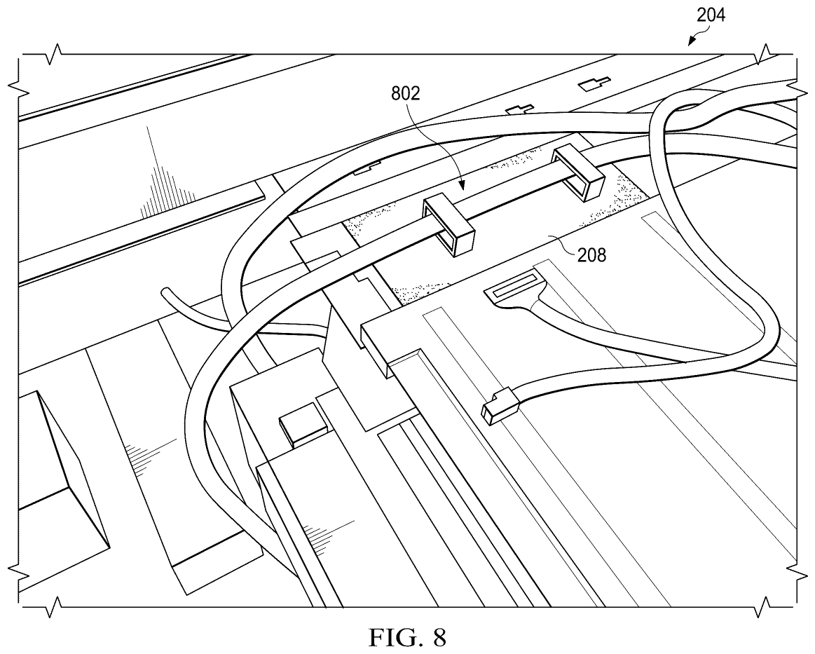

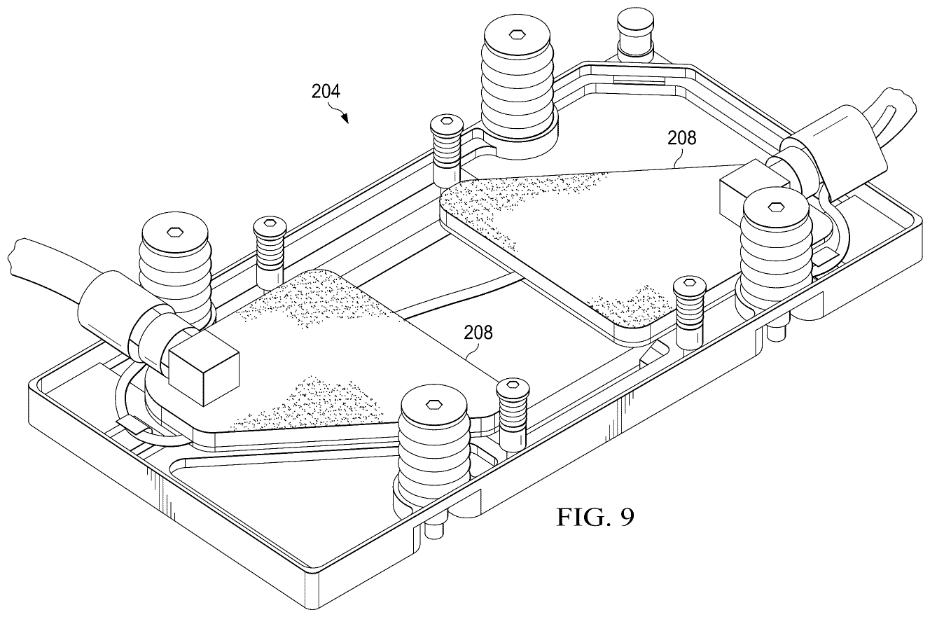

In a use case example, FIG. 7 illustrate the chassis 204, with the absorbent material 208 positioned at locations at known liquid paths. In a use case example, FIG. 8 illustrates a cable channel 802 of the chassis 204 with the absorbent material 208. In a use case example, FIG. 9 illustrates the absorbent material 208 at cold plate leak points of the chassis 204.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. An information handling system, including:
a chassis, including:
a computing component;
a cooling system to provide temperature management of at least the computing component, the cooling system including:
a plurality of fluid lines for transporting liquid proximate to the computing component, the liquid configured to provide cooling of the computing component;
a coupling connector between a first fluid line and a second fluid line of the plurality of fluid lines; and
an absorbent material positioned on a surface of the chassis proximate to the coupling connector such that the absorbent material is configured to absorb fluid that leaks from the coupling connector.

2. The information handling system of claim 1, the chassis further including:
an air flow system to provide airflow across the computing component and proximate to the fluid lines,
wherein the absorbent material does not obstruct the airflow.

3. The information handling system of claim 2, wherein:
the absorbent material has a first thickness when in a first state,
the absorbent material has a second thickness when in a second state, the second thickness greater than the first thickness, and
the absorbent material not obstructing the airflow when in the first state.

4. The information handling system of claim 3, wherein the first thickness of the absorbent material when in the first state does not obstruct the airflow.

5. The information handling system of claim 4, wherein the absorbent material transitions from the first state to the second state in response to the absorbent material absorbing fluid that leaks from the coupling connector.

6. The information handling system of claim 1, wherein the chassis further includes a reservoir at the surface, the absorbent material positioned at least in the reservoir.

7. The information handling system of claim 1, wherein the absorbent material is a sponge-based material.

8. The information handling system of claim 1, wherein the absorbent material includes a super absorbent polymer (SAP).

9. The information handling system of claim 1, further including:
one or more sensors positioned on the bottom surface proximate to the coupling connector, the sensors configured to detect liquid at the surface of the chassis and/or the absorbent material, and generate a signal in response to the detection of liquid.

10. The information handling system of claim 1, wherein the computing component is a printed circuit board (PCB).

11. An information handling system, including:
a chassis, including:
a computing component;
a cooling system to provide temperature management of at least the computing component, the cooling system including:
a plurality of fluid lines for transporting liquid proximate to the computing component, the liquid configured to provide cooling of the computing component;
a cooling component; and
a coupling connector between a first fluid line of the plurality of fluid lines and the cooling component; and
an absorbent material positioned on a surface of the chassis proximate to the coupling connector such that the absorbent material is configured to absorb fluid that leaks from the coupling connector.

12. The information handling system of claim 11, the chassis further including:
an air flow system to provide airflow across the computing component and proximate to the fluid lines,
wherein the absorbent material does not obstruct the airflow.

13. The information handling system of claim 12, wherein:
the absorbent material has a first thickness when in a first state,
the absorbent material has a second thickness when in a second state, the second thickness greater than the first thickness, and
the absorbent material not obstructing the airflow when in the first state.

14. The information handling system of claim 13, wherein the first thickness of the absorbent material when in the first state does not obstruct the airflow.

15. The information handling system of claim 14, wherein the absorbent material transitions from the first state to the second state in response to the absorbent material absorbing fluid that leaks from the coupling connector.

16. The information handling system of claim 11, wherein the chassis further includes a reservoir at the surface, the absorbent material positioned at least in the reservoir.

17. The information handling system of claim 11, wherein the absorbent material is a sponge-based material.

18. The information handling system of claim 11, wherein the absorbent material includes a super absorbent polymer (SAP).

19. The information handling system of claim 11, further including:
one or more sensors positioned on the bottom surface proximate to the coupling connector, the sensors configured to detect liquid at the surface of the chassis and/or the absorbent material, and generate a signal in response to the detection of liquid.

20. The information handling system of claim 11, wherein the computing component is a printed circuit board (PCB).
